(19) United States
(12) Patent Application Publication
(10) Pub. No.: US 2023/0074639 A1
(43) Pub. Date: Mar. 9, 2023

(54) SEMI ADDITIVE MANUFACTURING PROCESS FOR PRODUCING PRINTED ELECTRONICS

(71) Applicant: CREATIVE IC3D LTD, Beer Sheva (IL)

(72) Inventor: Yacov MAZUZ, Rishon LeTsiyon (IL)

(21) Appl. No.: 17/795,342

(22) PCT Filed: Jan. 27, 2021
(86) PCT No.: PCT/IL2021/050089

§ 371 Date: Jul. 26, 2022

(30) Foreign Application Priority Data
Jan. 27, 2020 (IL) 272290

(51) Int. Cl. H05K 3/10; H05K 3/18; H05K 3/24; C25D 3/38; C23C 18/54

(52) U.S. Cl. CPC H05K 3/107; H05K 3/182; H05K 3/246; C25D 3/38; C23C 18/54; H05K 2203/0152; H05K 2203/0723

(57) ABSTRACT

A method for producing a structure, comprising providing a Composite Conductive Substrate (CCS) with a conductive layer, a non-conductive layer and a release layer, implemented on top of the conductive layer; determining an empty conductive pattern for each layer of the structure; printing a layer of non-conductive matter on the CCS, such that the conductive pattern of the first layer left empty from the non-conductive matter; on top of the release layer, below which the conductive layer is implemented, filling the empty conductive pattern with conductive matter by electroplating; peeling the filled conductive matter or peeling the filled conductive matter and the printed non-conductive matter, from the conductive layer of the CCS.

### FIELD OF THE INVENTION

The present invention relates to a semi additive manufacturing process for producing printed electronics. More particularly, the invention relates to a semi additive manufacturing process for producing printed electronics made from a conductive and non-conductive materials.

### BACKGROUND OF THE INVENTION

Over the years, the printed electronics (PE) industry has been using various printing techniques to produce, e.g., antennas, RFID chips, sensors etc. Recently this list is continuously increasing and today users' demands (for lower cost, flexible and smarter products) are a decisive factor for the selection of PE fabrication technologies, thereby, contributing to novel and better products. In recent years, the interest on flexible electronic systems (such as on non-planar surfaces) to be used, grew tremendously, particularly in areas such as aerospace, automotive, biomedical and health applications.

To fabricate printed flexible electronic 2D devices with required characteristics and performance, the optimal selection of conductive ink materials, flexible substrates, and the method of printing is of substantial importance. Conventionally, 2D electronic devices are manufactured mainly on rigid substrates by traditional methods such as photolithography, electroless plating and vacuum deposition. These methods include multi-stage processes and/or require high-cost equipment. In addition, a subtractive technique such as photolithography often uses environmentally undesirable chemicals that results usually in a large amount of wasted materials.

A better alternative for fabrication of electronic devices is an additive manufacturing processes, such as screen printing of conductive patterns using pastes containing conductive microparticles or nanoparticles (usually Ag, Ag alloys and recently Cu). This technique is very simple to operate and involves only two steps: printing and curing the obtained patterns while the resulting conductivities are almost close to that of the bulk metal (10%-60%). A large variety of direct writing and additive deposition techniques are available for fabrication of conductive elements of 2D electronic devices, such as spin, spray, dip and bar coating, as well as various printing methods like Flexo printing (a technique that uses a flexible printing plate) and gravure. Among the printing technologies, Drop-On-Demand (DOD) inkjet printing is a powerful technology which gained a lot of interest since it is a non-contact, fast, low-cost and ecofriendly method, which can be easily scaled up and results in minimal wastage of materials.

It is therefore an object of the present invention to provide a method and system for producing structures made from a conductive material and non-conductive structure.

It is another object of the present invention to provide a method and system for producing structures made from a conductive material with conductive characteristics that are preserved in a single order of magnitude throughout the whole structure.

Other objects and advantages of the invention will become apparent as the description proceeds.

### SUMMARY OF THE INVENTION

A method for producing a structure, comprising the following steps:
a. providing a composite conductive substrate (CCS) with a conductive layer, a non-conductive layer and a release layer, implemented on top of the conductive layer;
b. determining an empty conductive pattern for each layer of the structure;
c. printing a layer of non-conductive matter on the CCS, such that the conductive pattern of the first layer left empty from the non-conductive matter;
d. on top of the release layer, below which the conductive layer is implemented, filling the empty conductive pattern with conductive matter by electroplating; and
e. peeling the filled conductive matter or peeling the filled conductive matter and the printed non-conductive matter, from the conductive layer of the CCS.

The printed non-conductive matter may be formed using UV inkjet ink.

The non-conductive ink may comprise irradiation activated additives and is cured by irradiation from a digital micromirror device or from a UV-LED lamps.

The UV inkjet composition may be a free radical UV curable ink.

Electroplating may be performed by exposure to an electrolyte bath configured for electroplating.

The structure may be rinsed and dried before peeling. The structure may be optically examined after the layer is completed.

The free radical curable ink composition may comprise an adhesion promoter, including:
monomer acrylates;
acid modified acrylates;
oligomer acrylates;
any combination thereof.

The monomer acrylates may include PHOTOMER 4703 that is obtained from IGM RESINS.

The acid modified acrylates may include EB170 obtained from Allnex.

The oligomer acrylates may include PHOTOMER 4173, obtained from IGM RESINS.

The free radical curable ink composition may include a UV stabilizer or any combination of UV stabilizers.

The UV stabilizer may include compounds form the following group:
Irgastab UV 22;
Genorad 16.

A system for producing a structure with conductive material embedded in a non-conductive structure, comprising:
A. an automated optical inspection unit configured to determine the reliability and quality of any printing cycle by examining the produced layers so as to detect shorts, cuts and/or other defects in the layers;
B. a UV inkjet (dielectric) unit with at least one inkjet printing head and two UV LED lamps or a Digital Light Processing (DLP) with digital micromirror device (DMD);
C. at least one plating processing unit with an electrochemical cell containing liquid chemicals and anode, configured to fill empty conductive patterns on the structure with conductive matter by electroplating;
D. A rinsing and drying unit including an air knife and a heated air blower, the rinsing and drying unit is configured to rinse and dry newly produced layers of the structure;
E. a table with a conveyor or a linear stage, along which the 3D structure is moved through the units of the system during the various stages of production.

The structure may be produced using a roll to roll process.

One of the UV LED lamps may have a 365 nm or 385 nm or 395 nm or 405 nm wave length using for pinning the ink and the other UV LED lamp has a 365 nm or 385 nm or 395 nm or 405 nm wave length using for fully curing the ink.

The release layer may consist of, or based on, an admixture elected from the group consisting of:
chromium and chromium oxide;
nickel and nickel oxide;
chromium and chromium phosphate;
nickel and nickel phosphate;
nickel and nickel chromate.

The thickness of the release layer may be in the range between 0.001 micron and 0.04 microns.

The conductive layer may be based on copper, and the release layer is implemented on top of the conductive layer, such that the release layer allows separation of the filled conductive matter from the conductive layer.

Peeling may be performed by using a single sided, double sided acrylic adhesive tape, silicone adhesive tape or adhesive liquid.

The plating solution may have pH value of 2.5-4.5, for preserving the properties of the release layer.

The peeled structure may comprise electronic components attached thereto, such as Resistors; Capacitors; Transistors; Coils; Integrated circuits; Processors; Memory circuits; Logical gates.

The electroplated conductive layer structure may be plated by gold, Nickel or anti-tarnish layer. The plating processing unit may be an external unit.

### BRIEF DESCRIPTION OF THE DRAWINGS

In the drawings:

FIGS. 1A-1D schematically illustrate a semi additive manufacturing process for producing structure with conductive and non-conductive at different stages of production, according to an embodiment of the present invention;

FIG. 2 illustrates the result of the stage of printing a non-conductive layer structure on top of the conductive layer of the composite conductive substrate;

FIG. 3 illustrates the result of the electroplating stage, resulting an electroplated conductive layer structure, on top of the conductive layer of the composite conductive substrate;

FIG. 4 illustrates the result of the stage of peeling the electroplated conductive layer structure (ECLS) (the printed electronics) that has been grown on top of the conductive layer of the composite conductive substrate; and

FIG. 5 schematically illustrates a semi additive manufacturing system for producing a structure with conductive material and a non-conductive structure, according to an embodiment of the present invention.

### DETAILED DESCRIPTION OF THE INVENTION

The invention will now be described with reference to specific examples and materials. The following examples are representative of techniques employed by the inventors in carrying out aspects of the present invention. It should be appreciated that while these techniques are exemplary of specific embodiments for the practice of the invention, those of skill in the art, in light of the present disclosure, will recognize that numerous modifications can be made, mutatis mutandis, without departing from the spirit and intended scope of the invention.

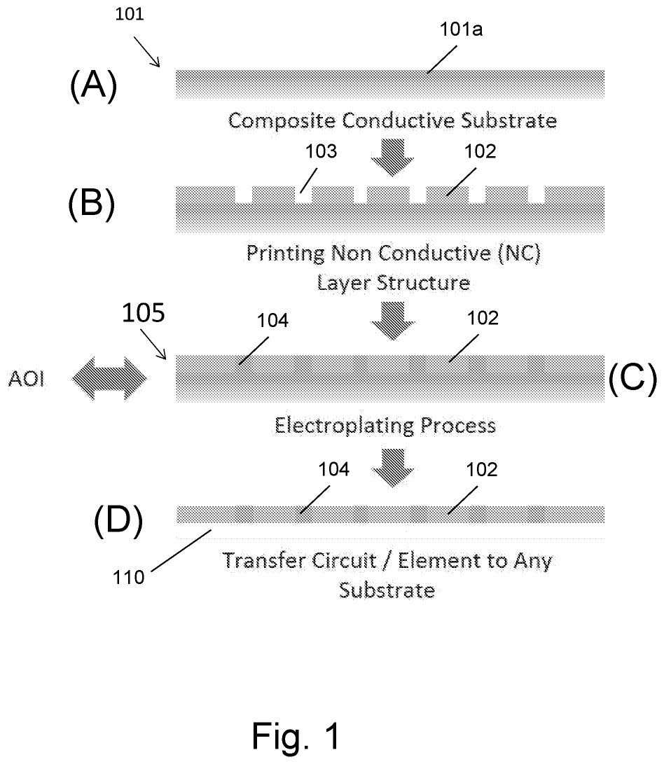

FIGS. 1A-1D schematically illustrate a semi additive manufacturing process of a structure at different stages of production, according to an embodiment of the present invention. In the first stage, shown FIG. 1A, a composite conductive substrate (CCS) 101 is placed on a moving base with its conductive layer 101a facing up. The base is moved to a UV inkjet unit (not shown in FIG. 1), with which a non-conductive layer structure (NCLS) (e.g. 102) is printed upon the CCS using non-conductive UV ink, as shown in FIG. 1B. The conductive pattern or template (e.g. 103) that is intended for this layer 105 is left empty, i.e. not printed over by the UV ink.

In the next stage the base is moved to a plating unit by which an electroplating process is performed and the empty conductive template 103 is filled with conductive matter, thereby creating an electroplated conductive layer structure (ECLS) 104 (as shown in FIG. 1C). The electroplating process may be performed by exposure to an electrolyte bath configured for electroplating. Because the conductive layer 101a is exposed beyond the empty template 103 in printed NCLS 102, it is able to act as an electrode that builds conductive matter during the electroplating process. The ECLS 104 is rinsed for cleaning the traces from the electroplating process, after which an air knife unit is used for drying the ECLS 104 from water traces. According to an embodiment of the invention, an automated optical inspection unit examines the produced ECLS 104, so as to detect shorts and/or cuts. Finally a complete layer 105 is achieved.

Once all printed electronics structure is completed (by the process described above), the printed structure is removed and transferred to another surface, by peeling the electroplated conductive layer structure (ECLS) 104 that has been grown on top of the composite conductive substrate 101a, or by peeling the printed non-conductive layer structure (NCLS) together with the electroplated conductive layer structure (ECLS) 104 that has been grown on top of the composite conductive substrate 101a, of the CCS and mount it on any desired substrate (i.e., the filled conductive matter (ECLS) is peeled alone or with the printed non-conductive matter (NCLS), from the conductive layer of the CCS). The result is a conductive structure, or a combination of a conductive and non-conductive structures.

It should be noted that although the 2D structure presented in FIGS. 1A-1D is a printed electronics, the present invention is not limited to printing of printed electronics and may be used to print any structure that comprises one or more layers with conductive and non-conductive areas.

According to an embodiment of the present invention, CCS 101 comprises an original conductive layer and a chemistry degradable or non-degradable non-conductive layer (NCL). The release layer is implemented on top of the original conductive (copper) layer, and the new conductive layer is built on top of the release layer, which allows the separation of the new built conductive later from the original conductive layer.

This process may also be implemented on other conductive layers such as silver, gold, titanium, graphene (carbon) layers, or on any other conductive material suitable to be removed by a chemical process (e.g., etching). In some embodiments of the invention, the thickness of the conductive layer is between 1 nm and 100 micron, and in other embodiments it is between 5 nm and 25 micron.

The release layer may essentially consist of (or may be based on) an admixture, selected from the group consisting of chromium and chromium oxide, nickel and nickel oxide, chromium and chromium phosphate, nickel and nickel phosphate, nickel and nickel chromate. In some embodiments of the invention, the thickness of the release layer has a thickness of between 0.001 micron and 0.04 micron.

The chemistry degradable or nondegradable NCL of the CCS may unlimitedly comprise Poly lactic acid (PLA), poly vinyl alcohol (PVA), Poly vinyl acetate (PA), or can be a polymeric substrate selected from polyester (polyethylene terephtalate, PET), polypropylene (PP), bi-oriented polypropylene (BOPP), polyethylene (PE), ethylenevinyl acetate (EVA), Nylon, polyamide, polyvinyl chloride (PVC), polystyrene (PS), a bio-degradable polymeric material, polyimide (Kapton), polyether etherketone (PEEK), polycarbonate, polyethylene naphthalate (PEN), polytetrafluoroethylene (Teflon), FR4, or a combination thereof.

According to an embodiment of the present invention, the non-conductive ink from which printed NCLSs are produced comprises UV curable ink composed of chemical components that allow it to polymerize and solidify in response to irradiation (e.g., UV), hence cure on a substrate. A typical UV curable ink composition may include a combination of chemical components such as: photoinitiators, monomers, oligomers, colorants, diluents, resins, stabilizers and surfactants. The typical and more common irradiation source for UV-curable inks is UV light source (including UV-LED or a Digital Light Processing (DLP) with digital micromirror device (DMD)). However, depending upon the ink ingredients, it may also be cured by irradiation using other energy sources, such as electron beam or UV laser beam. The curing process is a chemical reaction in which the activated monomers and oligomers ingredients of the ink polymerize to produce solid ink that is cured on a substrate. The polymerization reaction is initiated by irradiation of the ink that has been applied to a substrate, generally by using a UV light source, leading to photo-activation of the photoinitiators components of the ink mixture. These activated photoinitiators may now activate the monomers and oligomers of the ink composition and as a result a polymerization reaction may proceed. Depending on the ingredients of the ink composition, UV-curable inks exhibit varying degrees of viscosity at room temperature. Ink Jet printing requires low viscosity inks for jetting, but higher viscosity is essential for controlling drops on the printed surface.

The non-conductive ink further comprises irradiation activated additives and is cured by irradiation from a digital micromirror device or from a UV-LED lamps.

According to another embodiment of the present invention, the non-conductive ink comprises UV-curable ink compositions that are comprised of the following ingredients: photoinitiator (or a combination of photoinitiators) that constitutes between approximately 2% and approximately 10% (weight) of the ink composition; monomer (or a combination of monomers) that constitutes between approximately 68% and approximately 98% (weight) of the ink composition; oligomer (or a combination of oligomers) that constitutes between approximately 0% and approximately 30% (weight) of the ink composition; non curable volatile diluents (or a combination of diluents) that constitutes between approximately 0% and approximately 30% (weight) of the ink composition; colorants (or a combination of colorants) that constitutes between approximately 0% and approximately 10% (weight) of the ink composition; surfactant that constitutes between approximately 0.01% and approximately 2% (weight) of the ink composition; or any combination thereof.

According to yet another embodiment of the present invention, the non-conductive ink composition is a free radical UV curable ink. The free radical ink compositions comprise of the following ingredients: free radical photoinitiator (or a combination of photoinitiators) that constitutes between approximately 2% and approximately 10% (weight) of the ink composition; monomer (or a combination of monomers) that constitutes between approximately 68% and approximately 98% (weight) of the ink composition; oligomer (or a combination of oligomers) that constitutes between approximately 0% and approximately 30% (weight) of the ink composition; colorant (or a combination of colorants) that constitutes between approximately 0% and approximately 10% (weight) of the ink composition; surfactant that constitutes between approximately 0.01% and approximately 2% (weight) of the ink composition.

According to a further embodiment of the present invention, the non-conductive ink composition is a cationic-curable UV ink. The cationic ink compositions comprises the following ingredients: cationic photoinitiator (or a combination of photoinitiators) the constitutes between approximately 1% and approximately 10% (weight) of the ink composition; monomer (or a combination of monomers) that constitutes between approximately 30% and approximately 65% (weight) of the ink composition; oligomers (or combination of oligomers) that constitutes between approximately 0% and approximately 30% of the ink composition; non curable volatile diluent (or a combination of diluents) that constitutes between approximately 0% to about 30% (weight) of the ink composition; colorant (or a combination of colorants) that constitutes between approximately 0% and approximately 10% (weight) of the ink; surfactant that constitutes between approximately 0.01% to 2% (weight) of the ink composition.

According to some embodiments, UV-curable ink compositions are described herein. The ink composition may include photoinitiator (or a combination of photoinitiators), monomer (or a combination of monomers), oligomer (or a combination of oligomers), non-curable volatile diluent (or a combination of diluents), surfactant (or a combination of surfactant), colorant (or a combination of colorants) or any combination thereof. According to some embodiments, the ink composition may be cured by a free radical mechanism, named herein free radical curable ink. According to some embodiments, the free radical curable ink may include free radical photoinitiator. The free radical photoinitiator may include Hydroxyketone, Aminoketones, Mono AcylPhosphine, Bis Acyl Phosphine, Phosphine oxide, Thioxanthone, polymeric Thioxanthone or any combination thereof. For example: Hydroxyketone containing photoinitiators may include such compounds as, but not limited to: Irgacure 184, Irgacure 500, Darocur 1173, Irgacure 2959, all may be obtained from BASF Ciba Specialty Chemicals (former Ciba Specialty Chemicals). Aminoketones containing photoinitiators may include such compounds as, but not limited to: Irgacure 369, Irgacure 907, irgacure 1300 all may be obtained from BASF (former Ciba Specialty Chemicals). Mono Acyl phosphine and/or Bis Acyl Phosphine containing photoinitiators may include such compounds such as, but not limited to: Darocur TPO, Darocur 4265, Irgacure 819, Irgacure 819DW, Irgacure 2022 all may be obtained from BASF (former Ciba Specialty Chemicals). Thioxanthone containing photoinitiators may include such compounds such as, but not limited to: SpeedCure 2-ITX, SpeedCure CPTX, SpeedCure DETX all may be obtained from LAMBSON. Polymeric Thioxanthone containing photoinitiators may include such compounds such as, but not limited to: SpeedCure 7010, SpeedCure 7010-L, SpeedCure PTX-800 all may be obtained from LAMBSON. However, it should be clear to one of skill in the art that any applicable photoinitiator either known today or to be developed in the future, may be applicable to the present invention and is contemplated.

According to some embodiments of the present invention, a free radical curable ink composition may include a monomer (or any combination of monomers). The monomer (or a combination of monomers) may include monofunctional acrylates, difunctional acrylates, trifunctional acrylates, highly functional acrylates, monofunctional methacrylates, difunctional methacrylates, trifunctional methacrylates, non-acrylic monomers, or any combination thereof. For example: Monofunctional acrylate monomers may include such compounds as, but not limited to: CD217, SR256, SR257C, CD278, SR285, SR335, SR339C, SR395, SR410, SR420, SR440, SR484, SR489, SR495B, SR504, SR506D, SR531, CD586D, SR789, all may be obtained from Sartomer Co (today part of Arkema group). Difunctional acrylate monomers may include such compounds as, but not limited to: SR238, SR259, SR268US, SR272, SR306, SR341, SR344, SR349, SR601E, SR602, SR4423, SR508, CD536, CD595, SR606A, SR610, SR802, SR833S, SR9003, all may be obtained from Sartomer Co (today part of Arkema group). Trifunctional acrylate and/or highly functional acrylates monomers may include such compounds as, but not limited to: SR295, SR351, SR355, SR368, SR399, SR399LV, SR444D, SR454, SR499, SR502, SR9035, SR415, SR492, SR494, SR9020, CD9021, all may be obtained from Sartomer Co (today part of Arkema group). Monofunctional methacrylates, difunctional methacrylates, trifunctional methacrylates monomers may include such compounds as, but not limited to: SR203, SR313A, SR313E, SR340, SR421A, SR423D, SR550, SR604, SR101K, SR348L, SR348C, SR150, SR540, SR480, SR205, SR206, SR209, SR210, SR214, SR231, SR239A, SR252, CD262, SR297J, SR603OP, SR834, SR350, all may be obtained from Sartomer Co (today part of Arkema group). However, it should be clear to one of skill in the art that any applicable monomer either known today or to be developed in the future, may be applicable to the present invention and is contemplated.

According to some further embodiments of the present invention, a free radical curable ink composition may include an oligomer (or any combination of oligomers) that may include epoxy acrylates, aliphatic urethane acrylates, aromatic urethane acrylates, methacrylates and polyester acrylates with low viscosity or any combination thereof. For example: epoxy acrylates may include such compounds as, but not limited to: CN109, CN129, CN131B, CN132, CN133, CN152, may be obtained from Sartomer Co (today part of Arkema group), EBECRYL 113, EBECRYL 3300, EBECRYL 3416, may be obtained from Allnex. Aliphatic urethane acrylates may include such compounds as, but not limited to: CN9245, CN 9251, CN922, CN925, CN9276, CN991, may be obtained from Sartomer Co (today part of Arkema group), EBECRYL 225, EBECRYL 1290, EBECRYL 4858, EBECRYL 8210, EBECRYL 8402 may be obtained from Allnex. Aromatic urethane acrylates may include such compounds as, but not limited to: CN9165, CN 9167, CN9196, CN992, may be obtained from Sartomer Co (today part of Arkema group). Polyester acrylates may include such compounds as, but not limited to: CN203, CN204, CN2505, CN293, may be obtained from Sartomer Co (today part of Arkema group). methacrylates may include such compounds as, but not limited to: CN159, may be obtained from Sartomer Co (today part of Arkema group). However, it should be clear to one of skill in the art that any applicable oligomer either known today or to be developed in the future, may be applicable to the present invention and is contemplated.

According to some further embodiments of the present invention, the free radical curable ink composition may include an adhesion promoter (or any combination of adhesion promoter) that may include monomer acrylates, acid modified acrylates, oligomer acrylates, or any combination thereof. For example: monomer acrylates may include such compounds as, but not limited to: PHOTOMER 4703, may be obtained from IGM RESINS. Acid modified acrylates may include such compounds as, but not limited to: EB170, may be obtained from Allnex. Oligomer acrylates may include such compounds as, but not limited to: PHOTOMER 4173, may be obtained from IGM RESINS. However, it should be clear to one of skill in the art that any applicable oligomer either known today or to be developed in the future, may be applicable to the present invention and is contemplated.

According to some further embodiments of the present invention, the free radical curable ink composition may include a UV stabilizer (or any combination of UV stabilizers). For example, the UV stabilizer may include such compounds as, but not limited to: Irgastab UV 22 may be obtained from BASF Corporation (Ludwigshafen, Germany), Genorad 16 may be obtained from Rahn USA Corporation (Aurora, Ill., U.S.A.). However, it should be clear to any one skilled in the art that any applicable UV stabilizer either known today or to be developed in the future, may be applicable to the present invention and is contemplated.

According to some embodiments, the free radical curable ink includes a colorant. The colorant may include pigment, dye or any combination thereof. The colorants may be transparent, unicolor or composed of any combination of available colors.

According to some embodiments of the present invention, the free radical curable ink composition may include surfactant (or a combination of surfactants). For example, surfactant may include such compounds as, but not limited to: BYK-361N, BYK-378, BYK-1791, BYK-1794, BYK-1798, BYK-3441, BYK-3455, BYKJET-9150, BYKJET-9151, BYKJET-9152, BYK-UV 3500, BYK-UV 3505, BYK-UV 3530, BYK-UV 3575, obtained from BYK-Chemie (a member of ALTANA), TegoRad 2100, TegoRad 2200N, TegoRad 2250, TegoRad 2300, TegoRad 2500, TegoRad 2700, TegoAirex 920, TegoVariPlus 3350 UV, TegoVariPlus SK, obtained from Evonik industries (former Degussa AG) or any combination thereof. However, it should be clear to one of skill in the art that any applicable surfactant either known today or to be developed in the future, may be applicable to the present invention and is contemplated.

According to some embodiments, the UV-curable ink composition may exhibit a viscosity value of about 5 to about 50 centiPoise (cP) at room temperature or about 5 to about 20 cP at working temperature. The working temperature may be between 20-70° C.

### Example 1

An example of a free radical curable ink composition, according to some embodiments is described in table I below. Each composition describes a single non-conductive ink that can be used to print a non-conductive layer structure, as indicated below:

TABLE I

| Trade Name | Chemical Type | 1 | 2 | 3 | 4 |
|---|---|---|---|---|---|
| SpeedCure 2-ITX | Thioxanthone | 2.98 | 3.5 | 3.53 | 3.46 |
| IRGACURE819 | Bis Acyl Phosphine | 2.98 | 3.07 | 3.09 | 3.03 |
| BYK361N | Polyacrylate | — | — | — | 0.32 |
| BYK 333 | Polyether-modified | 0.31 | 0.32 | 0.33 | — |
| | polydimethylsiloxane | | | | |
| SR506D | Isoboronyl acrylate | 27.75 | 28.58 | 29.4 | 28.85 |
| SR508 | Dipropylene glycol | 41.62 | 42.87 | 44.1 | 31.81 |
| | diacrylate | | | | |
| CN131B | Epoxy acrylate | — | — | — | 9.95 |
| SR833S | Tricyclodecanedimethanol | — | 9.07 | 10 | 9.02 |
| | diacrylate | | | | |
| EBECRYL 3300 | Epoxy acrylate | 9.02 | — | — | — |
| PHOTOMER 4173 | Acid functional acrylate | — | — | — | 8.51 |
| EBECRYL 170 | Acid modified acrylate | 4.86 | 3.5 | 3.53 | — |
| EBECRYL 4858 | Aliphatic urethane acrylate | 9.02 | 8.07 | 5 | 4.04 |
| IRGASTAB UV 22 | Quinone derivative | 1.46 | 1 | 1.03 | 1.01 |

According to an embodiment of the present invention, the plating process is based on methods for electroplating articles with metal coatings that generally involve passing a current between two electrodes in a plating solution where one of the electrodes is the article to be plated. A typical acid copper plating solution designed to plate pH sensitive substrates comprises dissolved copper (usually copper methanesulfonate but not limited to), an acid electrolyte such as methanesulphonic acid in an amount sufficient to impart conductivity to the bath, and proprietary additives to adjust the pH to 2.5-4.5, so as to preserve the properties of the release layer and to improve the uniformity of the plating and the quality of the metal deposit. Such additives may include brighteners, levelers, complexants, surfactants, suppressants, etc. However, it should be clear to one of skill in the art that any applicable copper plating process (either known today or to be developed in the future), may be applicable, as well, without departing from the method proposed by the present invention.

### Example 2: A Typical Acid Copper Plating Solution Designed to Plate pH Sensitive Substrates

Table II specifies possible copper plating formulation conditions:

TABLE II

| | | Range |
|---|---|---|
| 1 | H₂O | 100 ml/L |
| 2 | *COPPER GLEAM RG-10 Complexer | 135-165 ml/L |
| 3 | SOLDERON LG Complexor | 550-630 ml/L |
| 4 | **Chloride ion | 40-80 ppm |
| | ***pH | 2.5-4.5 |
| 5 | COPPER GLEAM CLX Carrier | 2-15 ml/L |
| 6 | COPPER GLEAM CLX Additive | 3-20 ml/L |
| 7 | H₂O | Complete to the |
| | | required volume |
| | Temperature | 22-28° C. |
| | Current Density | 0.1-0.5 A/dm2 |

* contain copper(II) methanesulfonate and methanesulphonic acid

** for 100 liters of bath 2.2 ml of concentrated hydrochloric acid (37%)=10 ppm chloride

*** the pH to the required parameter is adjusted using 20% sodium hydroxide solution.

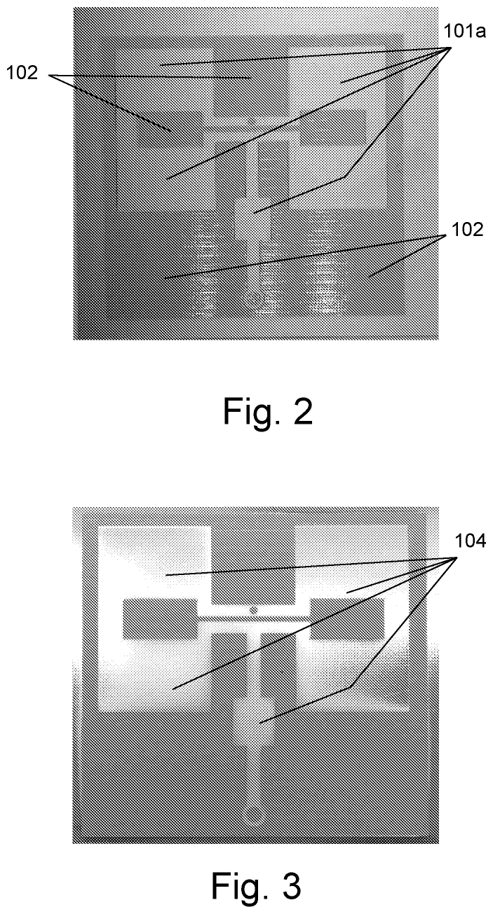

Plating experiments were done using an equipped MICROCELL TANK MODEL II (manufactured by YAMAMOTO-MS, Shibuya City, Tokyo, Japan) contain copper plating solution described in table I and example of printed non-conductive layer structure on top of the conductive layer 101a of composite conductive substrate 101 (as illustrated in FIG. 2). At the first step, 0.3-0.4 A/dm2 electric current is applied without air agitation for up to 5 min (optimally, 2-3 min.). At the next step, predetermined current is applied with air agitation for a time period required to obtain the desired copper plating thickness. At the end of the plating process, the plated structure is rinsed with water, dried and the ECLS peeling (from the structured area with or without the ink) is examined using single or double sided adhesive tape. The printed NCLS may be transferred, dependent of the type of printed ink.

Anti-tarnish treatment or immersion gold may be performed (using appropriate materials) before or/and after peeling.

According to an embodiment of the present invention, the plating process is performed by: In situ direct current (DC) plating, In situ pulse plating, In situ periodic pulse reverse plating (PPR), vertical plating, horizontal plating, or a combination thereof.

FIG. 2 illustrates the result of the stage of printing a non-conductive layer structure on top of the conductive layer 101a of composite conductive substrate 101. Typically, the conductive layer 101a is a copper layer, which is the upper surface of the composite conductive substrate (on top of which a conductive matter should be grown), on top of which the release layer is implemented. The non-conductive layer structure 102 may be digitally printed using non-conductive free radical curable ink and is used as a masking layer for preventing the growth of conductive matter in the masked areas. It can be seen that part of the surface of conductive layer 101a is below the surface of the printed non-conductive layer structure 102 (as can be seen also in FIG. 1B, which is a side view of the layers).

FIG. 3 illustrates the result of the electroplating stage, resulting an electroplated conductive layer structure, on top of the conductive layer 101a of the composite conductive substrate 101. It can be seen that the surface of the electroplated conductive layer structure 104 is aligned with the surface of the printed non-conductive layer structure 102 (as can be seen also in FIG. 1C, which is a side view of the layers). Actually, the electroplated conductive layer structure 104 (the printed electronics) is grown on top of the release layer, below which the conductive layer 101a is implemented. The release layer allows the separation of the filled conductive matter from the conductive layer 101a.

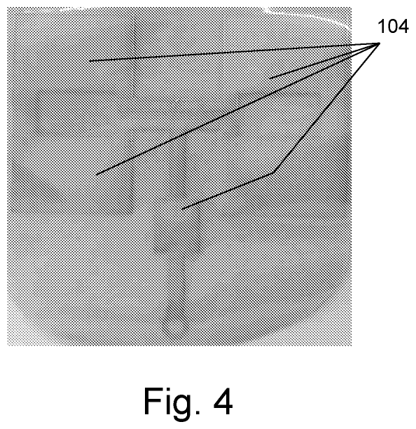

FIG. 4 illustrates the result of the stage of peeling the electroplated conductive layer structure (ECLS) 104 (the printed electronics) that has been grown on top of the conductive layer 101a of the composite conductive substrate 101. This peeling capability is achieved by the presence of the release layer on top of the conductive layer 101a of the CCS 101. Peeling may be performed, for example, by using a single sided or double sided acrylic adhesive tape a silicone adhesive tape or adhesive liquid.

After peeling, the printed electronics can be transferred and applied on any desired substrate 110 (as can be seen also in FIG. 1D, which is a side view of the layers).

Peeling may be performed for example, by using a single side adhesive tape with silicone adhesive tape. After peeling, the printed electronics can be transferred and applied on any desired substrate 110, on top of which, liquid adhesive is applied (e.g., two component polyurethane adhesive or two component epoxy adhesive), as can be seen also in FIG. 1D.

After lamination to an adhesive tape (single or double sided) or by applying liquid adhesive to a substrate, the grown conductive layer structure 104 (the printed electronics) can be easily peeled from the conductive layer 101a of composite conductive substrate 101.

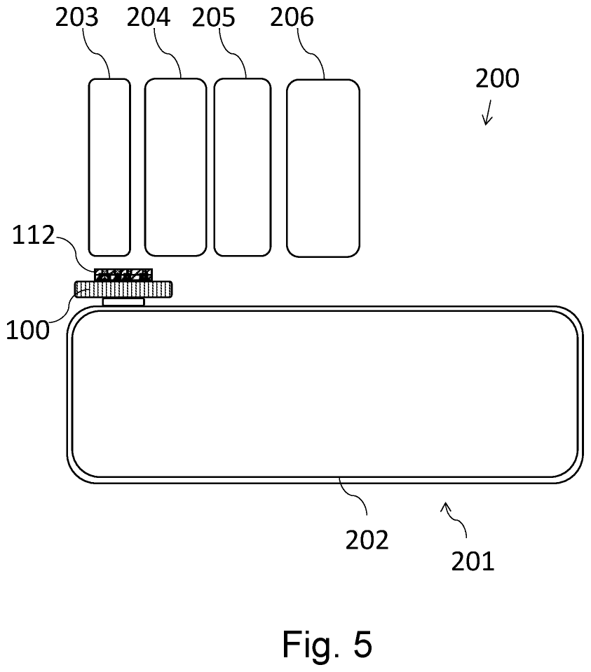

FIG. 5 schematically illustrates a semi additive manufacturing system for producing a structure with conductive material and a non-conductive structure, according to an embodiment of the present invention.

System 200 comprises a table 201 with a conveyor 202 (or a linear stage) along which the base is moved through the various stages of production. The structure 112 is printed on the composite conductive substrate (CCS) 101, which is mounted on the moving base 100, with its conductive layer 101a facing up.

An Automated Optical Inspection (AOI) unit 203 is optionally provided for determining the reliability and quality of any printing cycle by examining the produced layers so as to detect shorts, cuts and/or other defects in the layers.

A UV inkjet (dielectric) unit 204 is provided containing at least one inkjet printing head and two UV LED lamps. A non-conductive layer structure (NCLS) is built on top of the composite conductive substrate (CCS) 101 using an Inkjet printing head, after which the base 100 is moved under the UV LED lamps for the polymerization of the UV ink layer. According to an embodiment of the present invention, the first lamp has a 365 nm or 385 nm or 395 nm or 405 nm wave length using for pinning the ink and the second lamp has a 365 nm or 385 nm or 395 nm or 405 nm wave length using for fully curing the ink.

A plating processing unit 205 is provided, which uses an electrochemical cell containing liquid chemicals and anode suitable for filling empty conductive patterns on the structure with a conductive matter by electroplating. Conductive patterns are determined for each layer of the structure. The plating processing unit may be an external unit.

A rinsing and drying unit 206 is used for rinsing and drying the obtained structure. The copper building process may be performed separately from the printing system.

The obtained structure is optically examined after the layer is completed.

One or more electronic components may be attached to the peeled structure. Such electronic components may include Resistors, Capacitors, transistors, Coils, Integrated circuits, Processors, Memory circuits, Logical gates etc. that may be connected between conductors formed in a layer or in another layer, to form a complete electronic circuit.

Although embodiments of the invention have been described by way of illustration, it will be understood that the invention may be carried out with many variations, modifications, and adaptations, without exceeding the scope of the claims.

1. A method for producing a structure, comprising:
a. providing a composite conductive substrate (CCS) with a conductive layer, a non-conductive layer and a release layer, implemented on top of said conductive layer;
b. determining an empty conductive pattern for each layer of the structure;
c. printing a layer of non-conductive matter on said CCS, such that the conductive pattern of the first layer left empty from said non-conductive matter;
d. on top of said release layer, below which said conductive layer is implemented, filling the empty conductive pattern with conductive matter by electroplating; and
e. peeling the filled conductive matter or peeling the filled conductive matter and the printed non-conductive matter, from the conductive layer of the CCS.

2. The method for producing a structure according to claim 1, wherein the printed non-conductive matter is formed using UV inkjet ink.

3. The method for producing a structure according to claim 1, further comprising optically examining the structure after the layer is completed.

4. The method for producing a structure according to claim 1, wherein the non-conductive ink comprises irradiation activated additives and is cured by irradiation from a digital micromirror device or from a UV-LED lamps.

5. The method for producing a structure according to claim 1, wherein the UV inkjet composition is a free radical UV curable ink.

6. The method for producing a structure according to claim 1, wherein the electroplating is performed by exposure to an electrolyte bath configured for electroplating.

7. The method for producing a structure according to claim 1, further comprising rinsing and drying the structure before peeling.

8. The method for producing a structure according to claim 6, wherein the free radical curable ink composition comprises an adhesion promoter, including:
monomer acrylates;
acid modified acrylates;
oligomer acrylates;
any combination thereof.

9. The method for producing a structure according to claim 8, wherein the monomer acrylates include PHOTOMER 4703 that is obtained from IGM RESINS.

10. The method for producing a structure according to claim 8, wherein the acid modified acrylates include EB170 obtained from Allnex.

11. The method for producing a structure according to claim 8, wherein the oligomer acrylates may include PHOTOMER 4173, obtained from IGM RESINS.

12. The method for producing a structure according to claim 6, wherein the free radical curable ink composition includes a UV stabilizer or any combination of UV stabilizers.

13. The method for producing a structure according to claim 12, wherein the UV stabilizer includes compounds form the following group:
Irgastab UV 22;
Genorad 16.

14. A system for producing a structure with conductive material embedded in a non-conductive structure, comprising:
F. an automated optical inspection unit configured to determine the reliability and quality of any printing cycle by examining the produced layers so as to detect shorts, cuts and/or other defects in the layers;
G. a UV inkjet (dielectric) unit with at least one inkjet printing head and two UV LED lamps or a Digital Light Processing (DLP) with digital micromirror device (DMD);
H. at least one plating processing unit with an electrochemical cell containing liquid chemicals and anode, configured to fill empty conductive patterns on the structure with conductive matter by electroplating;
I. a rinsing and drying unit including an air knife and a heated air blower, the rinsing and drying unit is configured to rinse and dry newly produced layers of the structure;
J. a table with a conveyor or a linear stage, along which the 3D structure is moved through the units of the system during the various stages of production.

15. A system according to claim 14, in which the structure is produced using a roll to roll process.

16. A system according to claim 14, in which the one of the UV LED lamps has a 365 nm or 385 nm or 395 nm or 405 nm wave length using for pinning the ink and the other UV LED lamp has a 365 nm or 385 nm or 395 nm or 405 nm wave length using for fully curing the ink.

17. The method according to claim 1, wherein the release layer consist of, or based on, an admixture elected from the group consisting of:
chromium and chromium oxide;
nickel and nickel oxide;
chromium and chromium phosphate;
nickel and nickel phosphate;
nickel and nickel chromate.

18. The method according to claim 1, wherein the thickness of the release layer is in the range between 0.001 micron and 0.04 microns.

19. The method according to claim 1, wherein the conductive layer is based on copper and a release layer is implemented on top of said conductive layer, such that said release layer allows separation of the filled conductive matter from said conductive layer.

20. The method according to claim 1, wherein peeling is performed by using a single sided, double sided acrylic adhesive tape, silicone adhesive tape or adhesive liquid.

21. The method according to claim 1, wherein the electroplating is performed using plating solution has pH value of 2.5-4.5, for preserving the properties of the release layer.

22. The method for producing a structure according to claim 1, wherein the peeled structure comprises electronic components attached thereto.

23. The method for producing a structure according to claim 22, wherein the electronic components are selected from the group of:
Resistors;
Capacitors;
Transistors;
Coils;
Integrated circuits;
Processors;
Memory circuits;
Logical gates.

24. The method for producing a structure according to claim 6, further comprising plating the electroplated conductive layer structure by gold, Nickel or anti-tarnish layer.

25. The method for producing a structure according to claim 1, wherein the plating processing unit is an external unit.
